(19) United States
(12) Patent Application Publication
(10) Pub. No.: US 2016/0345467 A1
(43) Pub. Date: Nov. 24, 2016

(54) WATER COOLED POWER SUPPLY DEVICE SUITABLE FOR USING OPEN WATER SOURCE AS COOLING MEDIUM

(71) Applicant: GENIUS ELECTRONIC OPTICAL CO., LTD., TAICHUNG CITY (TW)

(72) Inventors: MING-CHI HUNG, TAICHUNG CITY (TW); MENG-HSUNG KE, TAICHUNG CITY (TW); CHIH-SHEN LIN, TAICHUNG CITY (TW)

(73) Assignee: Genius Electronic Optical Co., Ltd

(21) Appl. No.: 15/155,726

(22) Filed: May 16, 2016

(30) Foreign Application Priority Data
May 20, 2015 (TW) 104115993

(51) Int. Cl. H05K 7/20

(52) U.S. Cl. CPC H05K 7/20272; H05K 7/20927

(57) ABSTRACT

A water cooled power supply device suitable for using open water source as cooling medium includes: a power source box and a circulation module. The power source box includes a box, a power circuit module, and a waterproof unit between the inner space and an outer surface of the box. The power circuit module is disposed in the inner space. The circulation module includes a water cooling base, a pump, an input medium and an output medium. The water cooling base is disposed on the outer surface of the box, and sequentially includes an inlet, a flow space and an outlet which communicate with one another. The input medium has one end connected to the inlet and another end connected to the pump which communicates with the open water source. The output medium has one end connected to the outlet and another end connected to the open water source.

### BACKGROUND

1. Field of the Invention

The present invention relates to a power supply device, and more particularly to a water cooled power supply device suitable for using open water source as cooling medium.

2. Related Prior Art

Power supply devices are electronic components for supplying power to electric appliances. All power supply devices will produce heat during operation, and to avoid high temperature damage to the electronic products. Power supply devices would have different cooling requirements when power, environments or the electric appliances are different. Generally speaking, low-power or small scale power supplies are mostly cooled by natural air cooling or forced air cooling.

However, air cooling system is incapable of cooling high-power or large-scale power supply devices. Therefore, the water cooling system appeared on the market. However, the water cooling systems usually has a large size since it has to be equipped with containers for carrying water. The higher the requirement for cooling capacity, the larger the size of the container for carrying water will be. The power supply device for fishing lamps normally uses natural air cooling system due to the consideration of cost and space limit The natural air cooling system is usually a heat sink which is provided with a plurality of fins to increase cooling effect by increasing convection. The power supply device of the fishing lamp is disposed on a fishing boat and very likely to come into direct contact with seawater; therefore, seawater will erode the fins, and reduce the life and heat dissipation of the heat sink.

The present invention has arisen to mitigate and/or obviate the afore-described disadvantages.

### SUMMARY

The present invention is aimed at providing a water cooled power supply device suitable for using open water source as cooling medium, which overcomes the disadvantage that the air cooling system for a fishing lamp has insufficient cooling capability and short service life.

Therefore, a water cooled power supply device suitable for using an open water source as cooling medium in accordance with the present invention, comprises:

a power source box including: a box and a power circuit module, the box including an inner space, and a waterproof unit disposed between the inner space and an outer surface of the box, wherein the power circuit module is disposed in the inner space;

a circulation module including: a water cooling base, a pump, an input medium and an output medium; wherein:

the water cooling base is disposed on the outer surface of the box, and sequentially includes an inlet, a flow space and an outlet which communicate with one another;

the input medium has one end connected to the inlet and another end connected to the pump which communicates with the open water source; and

the output medium has one end connected to the outlet and another end connected to the open water source.

The power source circuit module is disposed in the waterproof power box, and the power box can be used in combination with the circulation module and the open water source, to produce a cooling effect.

These together with other objects of the invention, along with the various features of novelty which characterize the invention, are pointed out with particularity in the claims annexed to and forming a part of this disclosure. For a better understanding of the invention, its operating advantages and the specific objects attained by its uses, reference should be had to the accompanying drawings and descriptive matter in which there are illustrated preferred embodiments of the invention.

### BRIEF DESCRIPTION OF THE DRAWINGS

FIG. 1 is a perspective view of the water cooled power supply device suitable for using open water source as cooling medium in accordance with the preferred embodiment of the present invention;

FIG. 2 is a perspective view of the water cooled power supply device suitable for using open water source as cooling medium in accordance with another preferred embodiment of the present invention;

FIG. 3 is an illustrative view showing that the water cooled power supply device of the present invention is used in combination with other heat sources; and

FIG. 4 is another illustrative view showing that the water cooled power supply device of the present invention is used in combination with other heat sources.

### DETAILED DESCRIPTION

The present invention will be clearer from the following description when viewed together with the accompanying drawings, which show, for purpose of illustrations only, the preferred embodiment in accordance with the present invention.

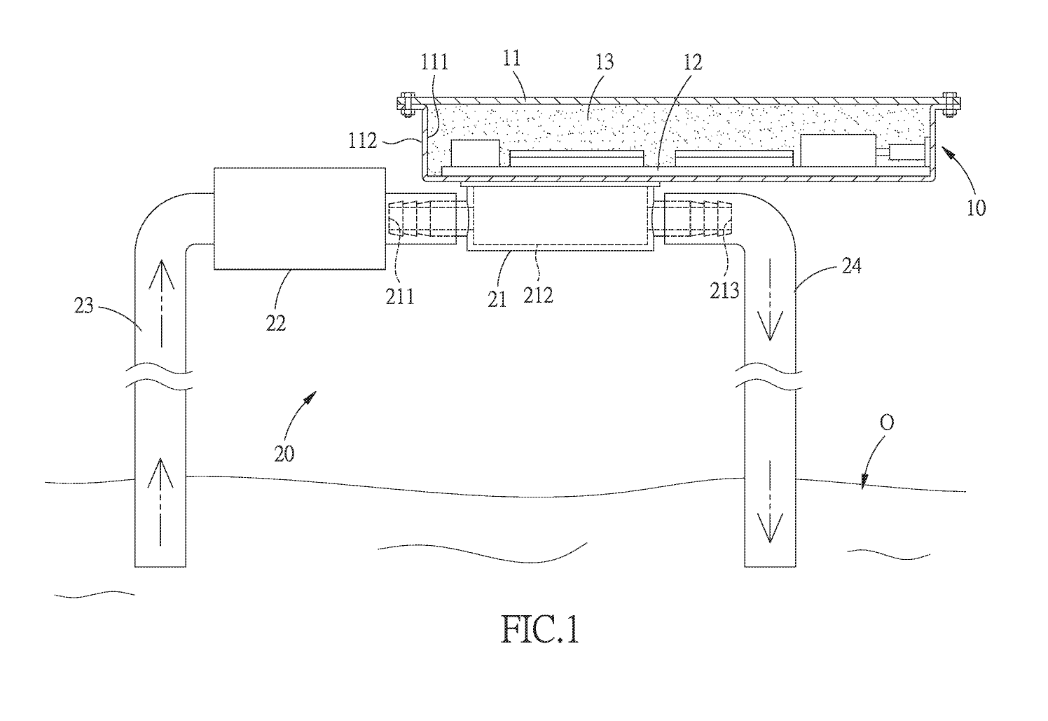

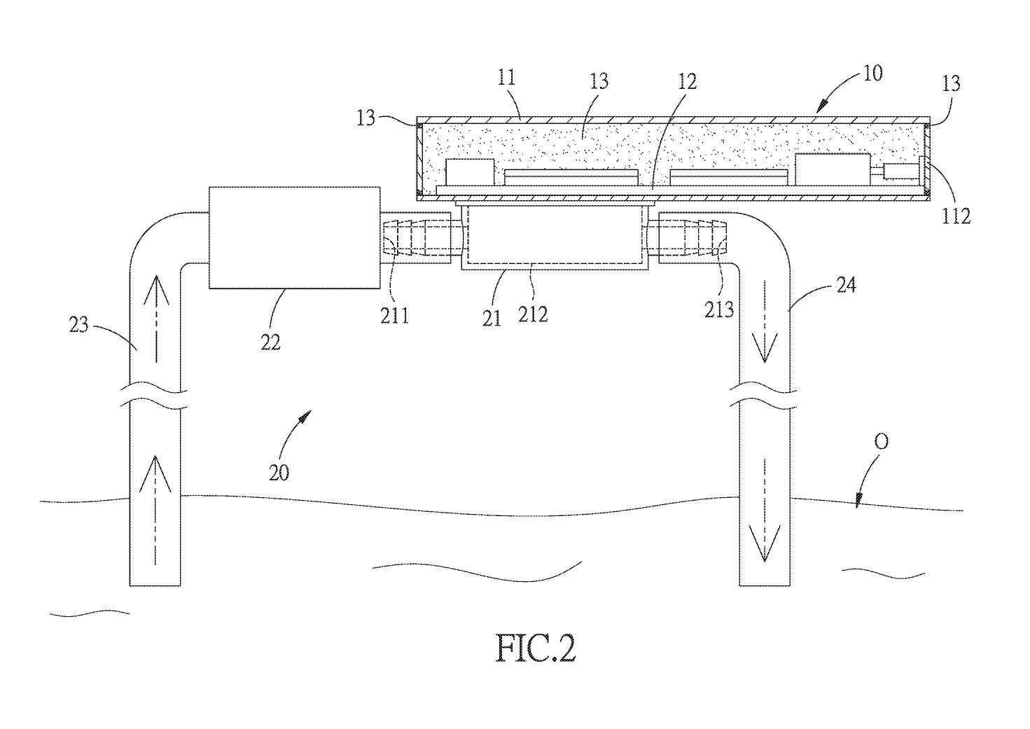

Referring to FIGS. 1 and 2, a water cooled power supply device suitable for using open water source O as cooling medium in accordance with the preferred embodiment of the present invention, comprise: a power source box 10 and a circulation module 20.

The power source box 10 includes a box 11 and a power circuit module 12. The box 11 includes an inner space 111, and a waterproof unit 13 disposed between the inner space 111 and an outer surface of the box 11. The power circuit module 12 is disposed in the inner space 111. As shown in FIG. 2, the box 11 includes a plurality of plates which define the inner space 111, and the plates are metal plates made of 316 stainless steel. The waterproof unit 13 is waterproof glue and can be disposed at joints between adjoining plates to bond the plates together. The inner space 111 can also be filled with the waterproof unit 13 to provide a waterproof seal for the entire power circuit module 12, as shown in FIGS. 1 and 2.

The circulation module 20 includes at least one water cooling base 21, one pump 22, at least one input medium 23 and one output medium 24.

The water cooling base 21 is disposed on the outer surface 112 of the box 11, and sequentially includes an inlet 211, a flow space 212 and an outlet 213 which communicate with one another. The flow space 212 in this embodiment is located in alignment with the power circuit module 12. In this embodiment, the water cooling base 21 is made of nylon 66 (polyhexamethylene adipamide) and ultraviolet resistant material.

The input medium 23 has one end connected to the inlet 211 and another end connected to the pump 22 which communicates with the open water source O. The open water source O is a water source which can not be closed or sealed. In this embodiment, the open water source O is ocean, and the input medium 23 is a water pipe.

The output medium 24 has one end connected to the outlet 213 and another end connected to the open water source O. The output medium 24 can be a water pipe.

When in use, the pump 22 pushes water from the open water source O into the flow space 212 of the water cooling base 21 via the input medium 23, the water flows through the flow space 212 to conduct away the heat generated from the power circuit module 12, and then out of the outlet 213 and finally flows back into the open water source O via the output medium 24, thus achieving a cooling affect.

Since the water cooled power supply device of the present invention can use open water source O as cooling medium, it is particularly suitable for use on a fishing boat which floats on the surface of the open water source O, the open water source O can be used as cooling medium, there is no need for the fishing boat to be equipped with water containers which is heavy and space consuming, and the cooling system is workable as long as the power source box 10 is equipped with the circulation module 20.

Since the present invention is particularly suitable for use in combination with the open water source O which can not be closed or sealed, which means that the water of the open water source O is very likely to splash on the power source box 10. In consideration this, the power circuit module 12 is disposed in the inner space 111 of the box 11 which is provided with the waterproof unit 13 which protects the power circuit module 12 from water damage. Besides, the box 11 is made of 316 stainless steel, so that it can be protected against water erosion. The outer surface of the box 11 is relatively small since it is provided with no fins, which can further protect the box 11 from erosion, consequently ensuring the normal operation of the power circuit module 12.

Still in consideration of the fact that the present invention is particularly suitable for use on a fishing boat which has to be exposed to an open and unsheltered natural environment, the water cooling base 21 is made of nylon 66 and ultraviolet resistant material, so as to achieve the effect of acid and alkali resistant, ultraviolet resistant and stress resistant. Therefore, the life of the circulation module 20 is extended.

The circulation module 20 of the present invention is not only applicable to the power source box 10, but also can be applied to other heat source 30 simply by increasing the number of the circulation modules 20. The heat source 30 can be light source.

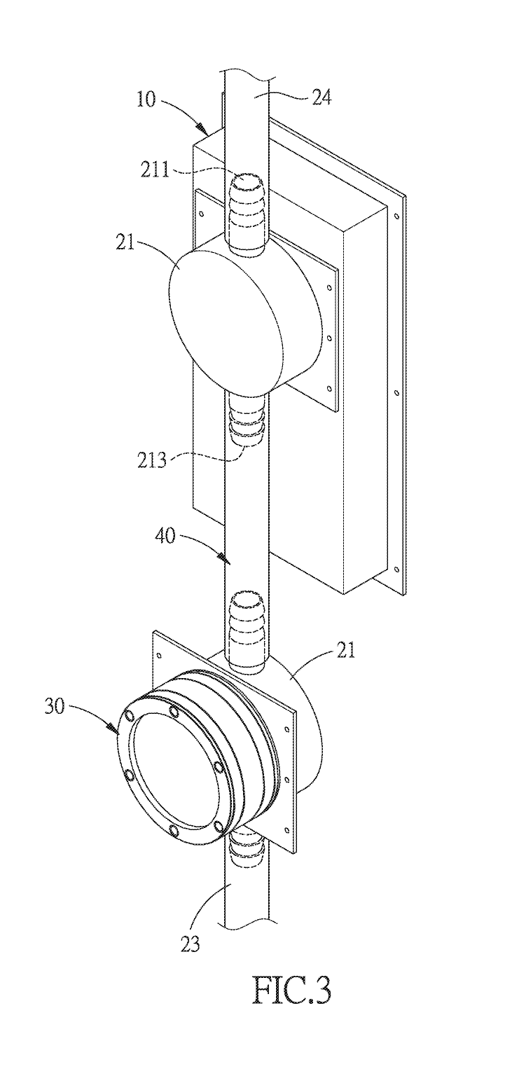

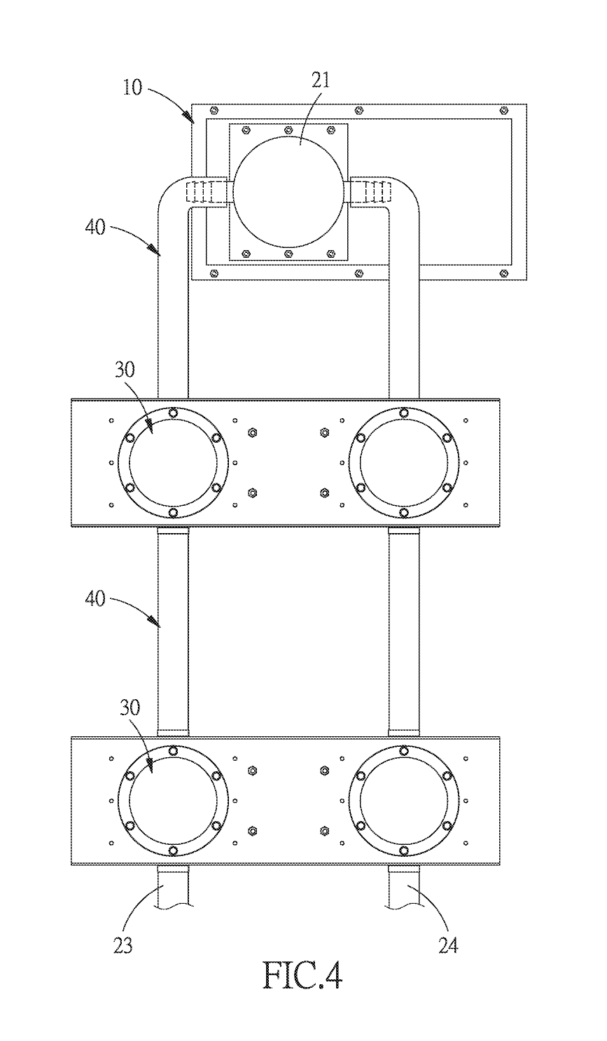

Besides, as shown in FIGS. 3 and 4, serial connecting pipes 40 can be used to connect heat sources 30 and the water cooling bases 21 in series, as long as the water of the open water source O can be introduced into and circulates in the respective heat sources 30 and the water cooling bases 21 of the power source box 10.

While we have shown and described various embodiments in accordance with the present invention, it is clear to those skilled in the art that further embodiments may be made without departing from the scope of the present invention.

What is claimed is:

1. A water cooled power supply device suitable for using an open water source as cooling medium, comprising:
a power source box including: a box and a power circuit module, the box including an inner space and an outer surface, and a waterproof unit disposed between the inner space and the outer surface of the box, wherein the power circuit module is disposed in the inner space;
a circulation module including: a water cooling base, a pump, an input medium and an output medium; wherein:
the water cooling base is disposed on the outer surface of the box, and sequentially includes an inlet, a flow space and an outlet which communicate with one another;
the input medium has one end connected to the inlet and another end connected to the pump which communicates with the open water source; and
the output medium has one end connected to the outlet and another end connected to the open water source.

2. The water cooled power supply device as claimed in claim 1, wherein the box includes a plurality of plates which define the inner space, and the waterproof unit is waterproof glue to be disposed at joints between each two said plates.

3. The water cooled power supply device as claimed in claim 2, wherein the plates are metal plates made of stainless steel.

4. The water cooled power supply device as claimed in claim 1, wherein the waterproof unit is waterproof glue, and the inner space of the box is filled with the waterproof unit.

5. The water cooled power supply device as claimed in claim 1, wherein the flow space is located in alignment with the power circuit module.

6. The water cooled power supply device as claimed in claim 1, wherein the water cooling base is made of nylon and ultraviolet resistant material.

7. The water cooled power supply device as claimed in claim 1, wherein there are a plurality of said circulation modules, and each said circulation module is provided with a heat source and connected to the power source box, in a manner that the water cooling base of each of the circulation modules is fixed to the heat source and the power source box.

8. The water cooled power supply device as claimed in claim 7, wherein the heat sources are light sources.
